(19) United States
(12) Patent Application Publication
(10) Pub. No.: US 2025/0149862 A1
(43) Pub. Date: May 8, 2025

(54) OPTICALLY PUMPED INTEGRATED SEMICONDUCTOR OPTICAL AMPLIFIER ARRAYS

(71) Applicant: Aloe Semiconductor Inc., Middletown, NJ (US)

(72) Inventor: Christopher R. Doerr, MIddletown, NJ (US)

(21) Appl. No.: 18/386,701

(22) Filed: Nov. 3, 2023

(51) Int. Cl. H01S 5/50; H01S 5/026; H01S 5/028; H01S 5/04

(52) U.S. Cl. CPC H01S 5/5027; H01S 5/0265; H01S 5/028; H01S 5/041

(57) ABSTRACT

An optical device includes an input port configured to receive pumping light; an optical splitter configured to split the pumping light into a plurality of waveguides; and a plurality of semiconductor optical amplifiers (SOAs) implemented on a single III-V die. Each SOA is configured to be optically pumped by receiving a portion of the pumping light from a respective one of the plurality of waveguides.

### TECHNICAL FIELD

The present disclosure generally relates to semiconductor optical amplifiers (SOAs).

### BACKGROUND

In optical communication systems, an optical transceiver utilizes one or more lasers to generate light signals that can be modulated with data for transmission over fiber optic links. Each laser can be pumped by an external energy source to power the laser. The external energy source provides energy which is absorbed into the gain medium of the laser, producing excited states in the laser's gain medium that results in stimulated emission of light. The light generated by the laser can then be modulated by data for transmission. The external energy source of the laser can be in the form of an electric current (electrical pumping) or another laser (optical pumping). For example, semiconductor lasers typically use current injection (electrical pumping) as an external energy source.

In some scenarios, multiple lasers can be used to transmit multiple streams of data that are multiplexed for transmission, for example by using wavelength division multiplexing (WDM) or polarization-division multiplexing (PDM). This can increase communication capacity and/or photon efficiency by multiplexing different signals over different channels (e.g., different wavelengths in WDM or different polarization modes in PDM) for simultaneous transmission through a single fiber. In scenarios of multiplexed transmission, separate lasers are typically implemented, each laser modulated by a separate data signal.

### SUMMARY

According to implementations of the present disclosure, an optical device implements an array of semiconductor optical amplifiers (SOAs) that are optically pumped. Optical pumping of the array of SOAs can enable much smaller dimensions of the SOA array and significantly higher yield, which can enable the SOA array to be implemented on a single III-V die.

In one aspect, an optical device includes an input port configured to receive pumping light; an optical splitter configured to split the pumping light into a plurality of waveguides; and a plurality of semiconductor optical amplifiers (SOAs) implemented on a single III-V die. Each SOA is configured to be optically pumped by receiving a portion of the pumping light from a respective one of the plurality of waveguides.

Implementations can include one or more of the following. The optical device, further including at least one of an optical transmitter or an optical receiver. The optical device, further including an electrically pumped laser configured to provide the pumping light into the input port for optically pumping the plurality of SOAs. The optical device, wherein the input port, the optical splitter, the plurality of waveguides, the plurality of SOAs, and the single III-V die are implemented on a photonic die, and wherein the electrically pumped laser is optically coupled to the photonic die. The optical device, wherein each SOA includes: an optical cavity configured to receive light from a waveguide among the plurality of waveguides; and an optical gain medium in the optical cavity configured to amplify light that propagates through the SOA. The optical device, wherein one or more of the plurality of SOAs on the single III-V die have a center-to-center spacing less than or equal to 100 μm. The optical device, wherein one or more of the plurality of SOAs on the single III-V die have a center-to-center spacing less than or equal to 50 μm. The optical device, wherein each of the plurality of SOAs includes etched facets. The optical device, wherein at least one of the etched facets are anti-reflection coated. The optical device, wherein the plurality of SOAs with etched facets are arranged in a trench in a photonic die with etched facets. The optical device, wherein the plurality of SOAs are attached to a silicon-photonics die, with epoxy, solder or other adhesive mechanism. The optical device, wherein the SOAs are epoxied upside down in a trench in the silicon-photonics die. The optical device, wherein for each SOA, there is no intentional p-type doping of semiconductor material near an active region of the SOA. The optical device, wherein there is no p-n junction in the SOAs. The optical device, wherein at least one of the plurality of SOAs is configured to provide optical gain in a laser cavity. The optical device, wherein at least one of the plurality of SOAs is configured to boost optical power of light that is output from an optical modulator. The optical device, wherein at least one of the plurality of SOAs is configured to pre-amplify optical power of light that is input to an optical receiver. The optical device, wherein a first SOA among the plurality of SOAs is configured to provide optical gain in a laser cavity, and wherein a second SOA among the plurality of SOAs is configured as a booster amplifier for light that is output from an optical modulator. The optical device, wherein a first SOA among the plurality of SOA is configured as a booster amplifier for light that is output from an optical modulator, and wherein a second SOA among the plurality of SOAs is configured as a pre-amplifier for light that is input to an optical receiver. The optical device, further including an electrically controllable heater in close proximity to the plurality of SOAs. The optical device, wherein each SOA includes a waveguide configured to propagate light through the SOA, and wherein the waveguide of each SOA is coupled to a respective silicon nitride (SiN) waveguide in the optical device. The optical device, wherein the optical splitter is configured to split the pumping light into the plurality of waveguides with adjustable splitting ratios. The optical device, further including a wavelength-division multiplexer connecting one of the plurality of waveguides to one of the SOAs that combines the pumping light and an input signal or an output signal.

In another aspect, an optical device includes a photonics die including an array of semiconductor optical amplifiers (SOAs) implemented on a single semiconductor die with no used electrical contacts to the SOAs.

Implementations can include one or more of the following. The optical device, further including an electrical heater on the array of SOAs. The optical device, further including an electrically pumped laser configured to provide pumping light for optically pumping the array of SOAs.

The details of one or more implementations of the subject matter of this disclosure are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example of a fiber optic transceiver with an electrically pumped laser;

FIGS. 2A and 2B illustrate examples of a fiber optic transceiver that implement wavelength division multiplexing (WDM) with separate electrically pumped input lasers;

FIG. 3 illustrates an example of a fiber optic WDM transceiver in which an array of semiconductor optical amplifiers (SOAs) are optically pumped by a single electrically pumped laser, according to implementations of the present disclosure;

FIGS. 4A and 4B illustrate other examples of a fiber optic WDM transceiver in which an array of SOAs are optically pumped by a single electrically pumped laser, according to implementations of the present disclosure;

FIG. 5 illustrates an example of a fiber optic WDM transceiver that includes both a transmitter and a receiver that utilize an array of SOAs that are optically pumped by a single electrically pumped laser, according to implementations of the present disclosure;

FIG. 6 illustrates an example of a fiber optic receiver based on polarization diversity that utilizes SOAs which are optically pumped by a single electrically pumped laser, according to implementations of the present disclosure; and

FIGS. 7A and 7B illustrate examples of a laser medium implemented by integrating an indium phosphide (InP) chip into a silicon photonics chip, according to implementations of the present disclosure.

### DETAILED DESCRIPTION

Typically, semiconductor lasers and semiconductor optical amplifiers (SOAs) use current injection to power the laser. For example, a III-V semiconductor material is placed inside a diode structure, and holes and electrons are injected into the active region from the p-and n-doped regions, respectively. While such a structure is extremely successful in industry, it has drawbacks. The p-doped III-V material has high optical losses which can require significant extra optical gain to overcome and can degrade the noise figure. In addition, the metal contact and doped material connecting to the p-n junction has a finite resistance which can cause significant heating during current injection. Furthermore, injection diodes typically have a low yield and high failure rate because defects can grow over time during current injection and lead to failure. Moreover, amplifiers on a single die must be widely spaced (typically 350 μm or more) because of electrical contact size and mutual heating issues. The low yield and high failure rate of current-injected SOAs is the primary reason why large arrays of lasers/SOAs cannot be integrated with low cost.

Silicon photonics is an optical integration platform that can leverage high-volume silicon processes used for electronics. Silicon photonics can be manufactured with very high yield, has low-loss waveguides, implements circuits that occupy a compact footprint, and has temperature-insensitive modulators and photodetectors. However, silicon photonics does not intrinsically provide any laser or SOA elements, because of its indirect bandgap. In many scenarios, III-V semiconductor materials have been integrated with silicon photonics to provide lasers/SOAs. These are either bonded on top of the silicon and further processed or finished III-V die are dropped into trenches. Both are difficult processes and require good electrical connections and heat sinking. Because of the relatively low yield and lifetime of electrically pumped lasers/SOAs and the fact that the lasers/SOAs cannot be fully tested until they are integrated in the silicon photonics die, it is generally not practical to integrate a large array of lasers/SOAs. For example, even if the yield of each laser/SOA is 85%, integrating an array of 8 lasers/SOAs has a yield of 0.85⁸=27%, an impractically low number.

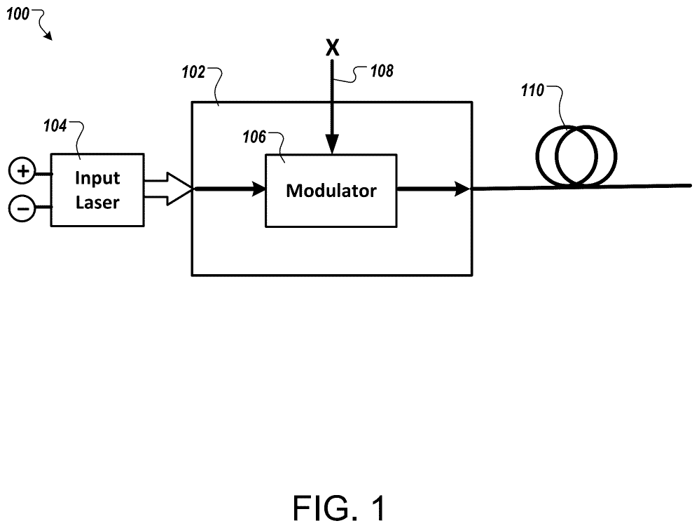

One example application for lasers/SOAs is for use in fiber-optic transceivers. FIG. 1 illustrates an example of a fiber optic transceiver. In this example, optical transceiver 100 includes a photonic integrated circuit (PIC) 102 with an input laser 104, which can be electrically pumped (e.g., via current injection).

In the example of FIG. 1, the electrically pumped laser 104 generates laser light that is input into modulator 106, which modulates the laser light with data 108 (denoted “X”). The modulated laser light is then transmitted over a fiber optical link 110.

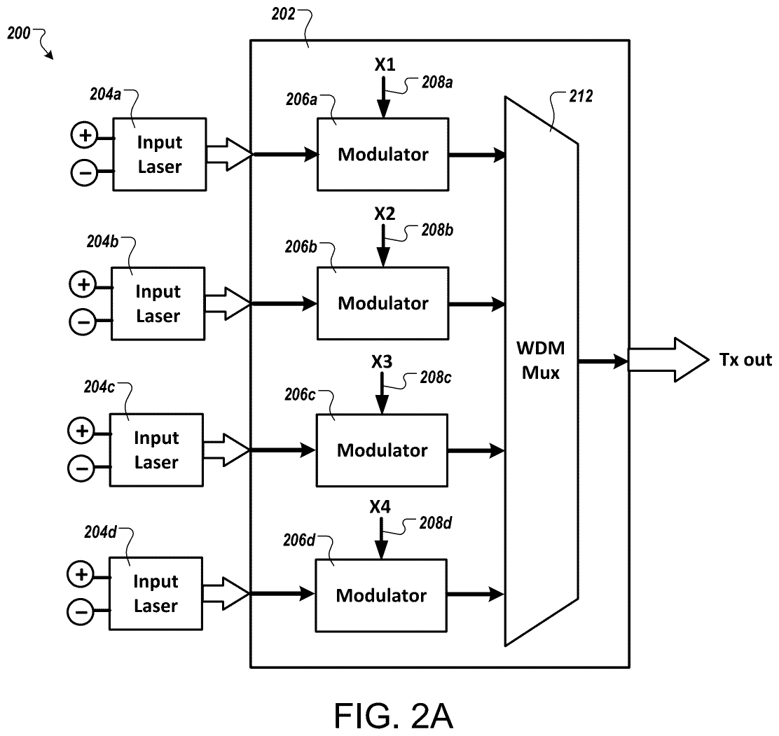

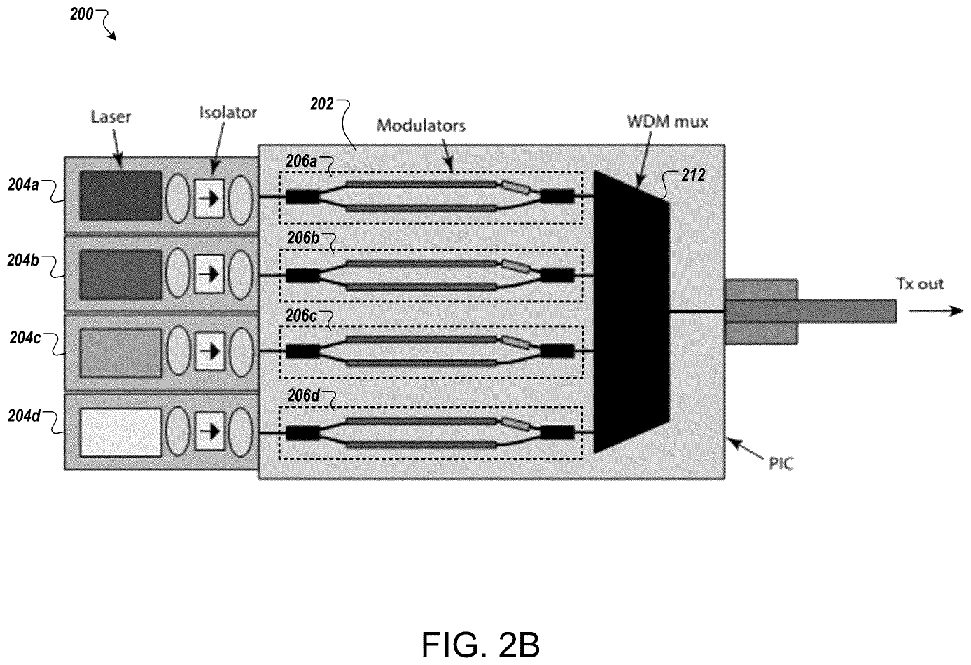

FIGS. 2A and 2B illustrate examples of fiber optic transceivers that implement wavelength division multiplexing (WDM) with separate electrically pumped input lasers. The examples of FIGS. 2A and 2B illustrate an FR4 transmitter, which is a short-reach transmitter with four coarse wavelength-division multiplexing (CWDM) channels. As an example, the four wavelengths can be 1271, 1291, 1311, and 1331 nm.

In the example of FIG. 2A, the optical transceiver 200 includes PIC 202 that uses individual electrically pumped lasers 204a, 204b, 204c, and 204d to generate input light for multiple modulators 206a, 206b, 206c, and 206d, respectively. The modulators 206a, 206b, 206c, and 206d modulate their respective input laser light with data 208a, 208b, 208c, 208d (X1, X2, X3, and X4), respectively. The modulated light signals are wavelength-division multiplexed in the WDM multiplexer 212, and the combined WDM signal is transmitted over fiber optic link 210.

FIG. 2B illustrates an example of a specific implementation of the FR4 transmitter of FIG. 2A. Each of the input lasers 204a, 204b, 204c, and 204d can implement a semiconductor laser (or SOA), collimation optics, an optical component (e.g., an optical isolator) that allows transmission of light in only one direction, and focusing optics. The laser light generated by each of the input lasers 204a, 204b, 204c, and 204d enters respective modulators 206a, 206b, 206c, and 206d. In the example of FIG. 2B, each of the modulators 206a, 206b, 206c, and 206d is implemented based on a Mach-Zehnder interferometer (MZI) implementation, in which optical signals propagate along the length of the modulator (e.g., from left to right in FIG. 2B) along two optical transmission paths. At the input of each modulator 206a, 206b, 206c, and 206d, an optical splitter splits the input light into the two optical transmission paths. At the output of each modulator 206a, 206b, 206c, and 206d, an optical combiner combines light output from the two optical transmission paths. The two optical transmission paths of each modulator 206a, 206b, 206c, and 206d can be implemented by waveguides formed in a semiconducting structure. The modulated laser light from each of the modulators 206a, 206b, 206c, and 206d enters a WDM multiplexer 212 which multiplexes the four modulated light signals for transmission. In the example of FIG. 2B, the transceiver 202 is implemented on (e.g., attached to) a photonic integrated circuit (PIC).

In the examples of FIGS. 2A and 2B, the transceiver 200 utilizes four electrically pumped lasers 204a, 204b, 204c, and 204d to provide four different sources of input light. Using separate electrically pumped lasers is expensive and consumes significant power. For example, in scenarios of 200-Gb/s per channel applications, the required laser power is high, typically ˜100 mW, which must operate at temperatures up to 70° C. The electrical power to drive these lasers (including the drive electronics) is typically at least 4 times higher than the optical power, thus more than ˜400 mW per laser.

As dates rates increase in optical transceivers, there will be more and more need for optical gain in order to close links. Optical gain generally offers a higher signal-to-noise ratio and higher bandwidth than electrical gain in a transimpedance amplifier. Especially, because an optically pumped SOA contains no p-doped material, the optical losses are lower, and thus the optical amplification has even lower noise.

According to implementations of the present disclosure, an optical device implements an array of SOAs which are optically pumped, instead of electrically pumped. The array of optically pumped SOAs is attached to one or more silicon photonic integrated circuits. In some scenarios, the array of optically pumped SOAs is implemented on a single III-V semiconductor die. For example, the array of SOAs can be implemented by integrating an Indium Phosphide (InP) chip into a silicon photonics chip. The array of optically pumped SOAs can perform a variety of functions, including lasers, pre-amplifiers, and post-amplifiers. The array of SOAs can be used to implement an optical transmitter and/or an optical receiver.

In the scenario of optically pumped SOAs, the optical gain elements in the array of SOAs are powered by one or more external optical energy sources. As such, in some implementations, there is no need for electrical pumping to power the SOAs, thereby enabling significantly higher yield and reliability. Optical pumping of the array of SOAs can provide various technical advantages, as compared to SOAs that are electrically pumped. For example, an optically pumped SOA chip can reduce or eliminate the need for electrical connections, heat sinking, and thermal dissipation. As a result, the optically pumped SOAs can be spaced very closely together, thus enabling numerous closely spaced SOAs to be arranged in an array that can be significantly smaller as compared to electrically pumped SOAs. For example, in some implementations, the array of optically pumped SOAs on a single III-V die have a center-to-center spacing less than or equal to 100 μm. In some implementations, the optically pumped SOAs on the single III-V die have a center-to-center spacing less than or equal to 50 μm.

An optically pumped laser/SOA requires an external optical pump source to induce population inversion in the laser/SOA. This external optical pump source is typically implemented using a separate electrically pumped laser with a shorter wavelength. While there is a potential disadvantage in requiring a separate electrically pumped laser as the external optical pump (in addition to the laser/SOA which is optically pumped by the external optical pump), this disadvantage can be mitigated by using a single external optical pump source to simultaneously pump an array of lasers/SOAs.

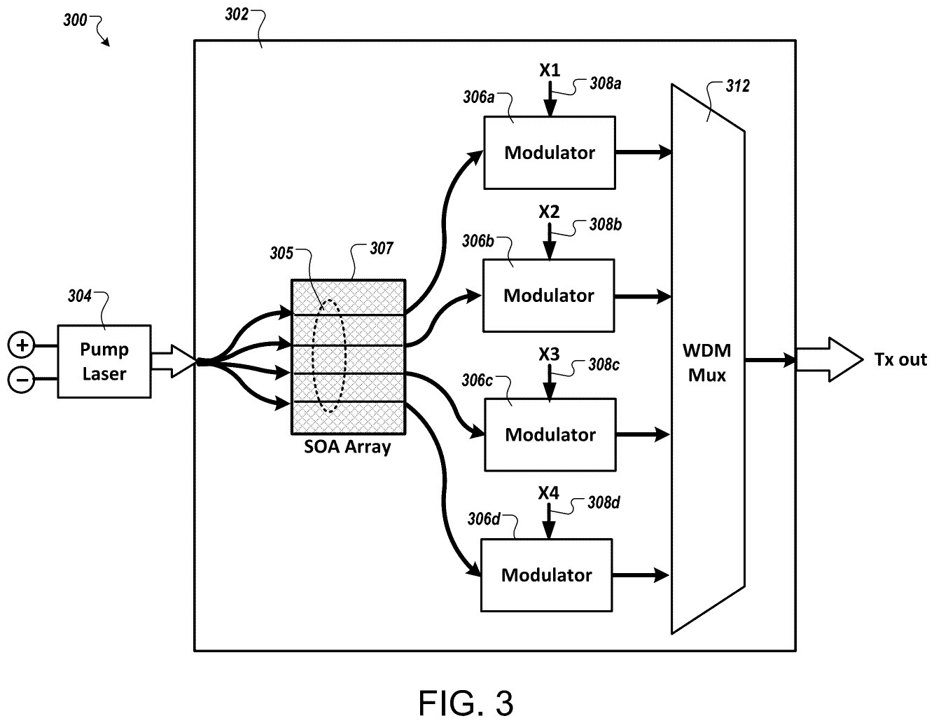

FIGS. 3, 4A, 4B, and 5 illustrate examples of fiber optic WDM transceivers in which an array of SOAs is powered a single external optical pump source that provides optical pumping for the array of SOA, according to implementations of the present disclosure. These examples illustrate an FR4 transmitter with four CWDM channels, but in general any number of CWDM channel can be implemented.

FIG. 3 illustrates an example of an optical transceiver 300 in which a PIC 302 implements a semiconductor die 307 (e.g., a III-V semiconductor die) in which an SOA array 305 includes four optically pumped SOAs. The four SOAs in the SOA array 305 are all simultaneously optically pumped by a single external pump source 304 (which can be implemented by an electrically pumped laser). The four optically pumped SOAs 305 are used to implement four CWDM lasers that provide input light to four modulators 306a, 306b, 306c, and 306d, which modulate their respective input light by data 308a, 308b, 308c, and 308d (X1, X2, X3, and X4), respectively. The four modulated light signals are then multiplexed by WDM multiplexer 312 for transmission.

As such, the optical transceiver 300 is able to use just a single electrically pumped laser 304 to simultaneously provide optical pumping for all four SOAs in the SOA array 305. Because the SOA array 305 is optically pumped by an external pump source, the SOA array 305 itself can be implemented on a chip that has no electrical connections and requires only minimal heat sinking, thus enabling straight-forward packaging (e.g., using active alignment and epoxy). Furthermore, in some scenarios, the SOA array 305 can be implemented with no electrical connections and minimal thermal dissipation, which can enable the SOAs in the array 305 to be spaced very closely. For example, the spacing (e.g., center-to-center spacing) of the optically pumped SOA on the single III-V die can be less than or equal to 100 μm. As another example, the spacing can be less than or equal to 50 μm. In some implementations, the spacing is 30 μm. As such, the closely spaced SOAs enable the SOA array 305 to be approximately 10 times smaller as compared to a scenario where the four SOAs in the array 305 had to implemented by four electrically pumped lasers. The PIC 302 can be implemented with silicon photonics, using silicon (Si) waveguides and/or silicon nitride (SiN) waveguides. In some implementations, the pump laser 304 generates pump light which enters PIC 302 through an input port and is guided to the SOA array 305 in SiN waveguides, which can be preferable to Si waveguides which exhibit significant single- and/or two-photon absorption at the pump wavelength.

In the example of FIG. 3, the SOA array 305 is utilized to implement four CWDM lasers that generate input light to the four modulators 306a, 306b, 306c, and 306d. In addition, the SOA array 305 can also be used for other purposes, such as amplification of the outputs of the modulators 306a, 306b, 306c, and 306d. Examples of this are provided next.

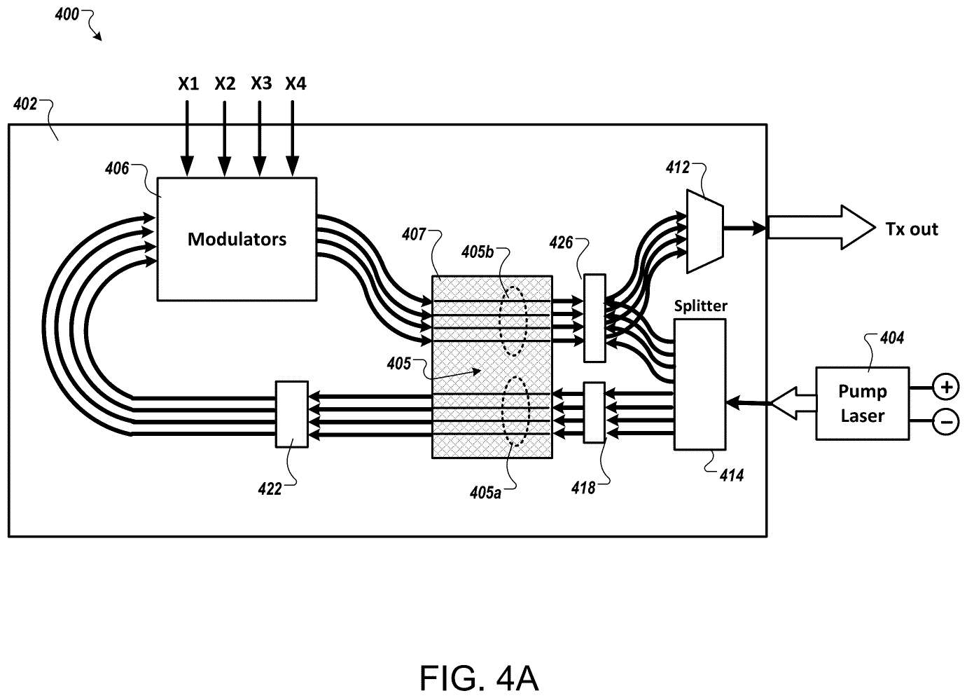

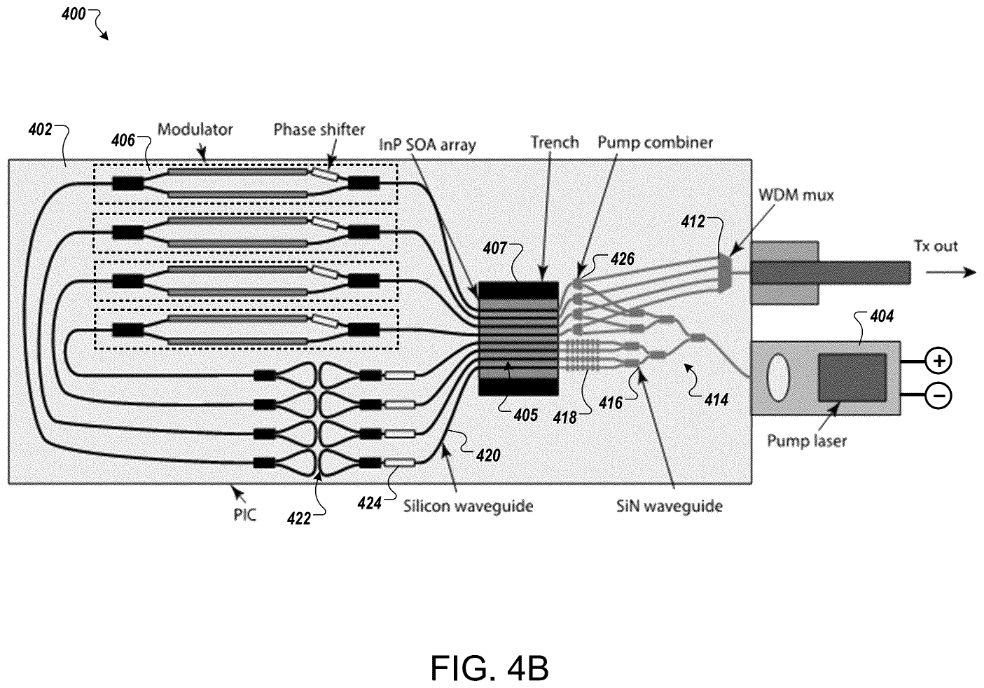

FIGS. 4A and 4B illustrate examples of an optical transceiver 400 in which a PIC 402 (e.g., a silicon photonics PIC) implements a semiconductor die 407 (e.g., a III-V semiconductor die) in which an SOA array 405 is used for the dual purpose of generating input laser light into, as well as amplifying the outputs of, a set of modulators 406. For ease of explanation, modulator 406 is shown as a single module in FIGS. 4A and 4B but can include multiple separate modulators (as in the example of FIG. 3).

To perform dual roles of input laser generation and output amplification, the SOA array 405 implements an array of eight optically pumped SOAs. Four of the SOAs in SOA array 405 (e.g., the lower four SOAs in SOA array 405 in FIGS. 4A and 4B) are used to create the four CWDM lasers that generate input light into the modulators 406. The other four SOAs in SOA array 405 (e.g., the upper four SOAs in SOA array 405 in FIGS. 4A and 4B) serve as booster amplifiers at the outputs of the modulators 406. All eight SOAs in the SOA array 405 are simultaneously pumped by a single external optical pump source 404 (e.g., an electrically pumped laser) which provides optical pumping for all eight SOAs. This electrically pumped laser 404 operates at a shorter wavelength than the lowest of the four CWDM wavelengths. The pump laser 404 can be directly coupled to the PIC with a lens, as shown in FIG. 4B, or remotely through a fiber. This splitting could be configurable using variable optical couplers. One implementation of a variable optical coupler is an MZI containing a thermo-optic phase shifter in one arm.

Because the SOA array 405 is optically pumped by an external pump source, the SOA array 405 can be implemented on an SOA chip that has no electrical connections and requires only minimal heat sinking, thus enabling straight-forward packaging (e.g., using active alignment and epoxy). Furthermore, in some scenarios, the SOA array 405 can be implemented without any electrical connections and minimal thermal dissipation in the SOAs, which enables the SOAs to be spaced very closely. For example, in some implementations, the SOAs in the SOA array 405 are spaced apart by only 30 μm, which makes the SOA array 405 about 10 times smaller than if the SOA were implemented with four individual electrically pumped lasers. This also facilitates optical alignment, since the total span of alignment is much smaller. Also, because the SOAs in the SOA array 405 are not electrically pumped, the SOA do not need burn-in, and their yield will be very high. Also, there is no intentional p-type doping of the III-V semiconductor material near an active region of the SOA. As such, because there is no p-doped III-V semiconductor (e.g., InP), the SOA internal loss is significantly lower, for example 10 cm⁻¹ less, allowing the carrier density to be approximately 30% smaller for the same gain. Also, the noise figure of the optical amplification will be reduced.

In the examples of FIGS. 4A and 4B, the transceiver 400 operates as follows. The external pump laser 404 generates input light which enters the silicon photonics PIC 402 through an input port and is split eight ways by a splitter 414 and are guided into the eight SOAs of the SOA array 405 by waveguides 416. Preferably the waveguides 416 that guide the light from the pump laser 404 to the SOA array 405 are SiN waveguides. SiN waveguides can be advantageous compared to Si waveguides, because Si becomes significantly absorptive at wavelengths below about 1100 nm, Si exhibits strong two-photon absorption, and SiN has a lower temperature dependence. The SiN waveguides 416 in the lower part of FIGS. 4A and 4B pass through a first reflector 418 (e.g., a grating such as a distributed Bragg reflector (DBR)) which has reflection peaks at the desired CWDM wavelengths. The first reflector 418 forms one end of laser cavities. The outputs of the first reflector 418 proceed to the lower four SOAs 405a in the SOA array 405. The outputs of the lower four SOAs 405a are guided through Si waveguides 420 where, at the other end of each of the four laser cavities, a second reflector 422 (e.g., a loop reflector) is implemented. A thermo-optic phase shifter 424 is implemented in each laser cavity to maintain the cavity mode near the Bragg reflection peak over temperatures. The loop reflectors 422 are coupled to other loop reflectors which tap off outputs from the four lasers. These taps proceed to the four modulators 406. In some implementations, there can also be a wavelength monitor integrated in the transceiver 400 to provide feedback to maintain the laser at a desired wavelength.

The modulators 406 (which can be implemented as four separate modulators as in FIG. 3) receive the four laser inputs and modulate the light with respective data X1, X2, X3, and X4. The modulators 406 can be implemented based on a MZI implementation, as described in FIG. 2B, or other configurations such as ring modulators. The modulated light signals which are output from the four modulators 406 proceed to the upper four SOAs 405b in the SOA array 405, where they are amplified. The upper four SOAs 405b are backward pumped by the optical pump 404 via pump couplers 426. Backward pumping is generally advantageous for high output power and low nonlinearity because it reduces pump depletion effects.

The outputs of the four upper SOA 405a proceed to a CWDM multiplexer 412, which multiplexes the four wavelengths into a single output, which couples to an output fiber. In some implementations, there can be an optional dielectric coating on one facet of the SOA 405 that transmits the signal wavelength but reflects the wavelength of the pump 404. This allows for a double-pass of the pump light, improving efficiency. In some implementations, no isolators are required, which is a significant savings over implementations that require four isolators. For example, in some implementations, the pump laser 404 does not implement an isolator because it is not exposed to the outside environment. Furthermore, in some implementations, the integrated lasers in the SOA array 405 do not implement isolators because they are long-cavity lasers and in the presence of optical feedback into the laser, the resultant increase in relative intensity noise (RIN) will occur at lower frequencies than III-V distributed-feedback lasers. Also, the relatively high insertion loss of the modulators 406 partially insulates the lasers in SOA array 405 from the outside environment. Alternatively, in some implementations, there can be isolators on the connections to the transceiver 400 to insulate the lasers from external reflections.

Various modifications can be made in the above-described scenario. For example, in some implementations, the pump splitters/combiners 414/426 can be variable (e.g., by using phase shifters). In some implementations, one or more components such as splitter 414, waveguides 416, first reflector 418, Si waveguides 420, second reflector 422, phase shifter 424, pump couplers 426, and/or CWDM multiplexer 412 can be implemented on the III-V semiconductor die with the SOA array 405. In some scenarios, multiple polarizations can be used (e.g., polarization division multiplexing or general IMDD scenarios), in which case an SOA can be implemented for each polarization. For example, in a dual-polarization (DP) scenario, two SOAs can be implemented for each polarization, in which case each waveguide (line) shown in the SOA array 405 of FIGS. 4A and 4B is actually two lines for the two polarizations. The SOA array 405 can be used in many types of configurations other than the configuration of FIG. 4A and 4B. For example, in some implementations, the SOA array can be used as pre-amplifiers for an optical receiver, as described next. The SOAs can be used in the C-band, O-band, or other optical bands of interest. The transceivers can be for intensity-modulated direct-detect (IMDD) systems, coherent systems, or other systems.

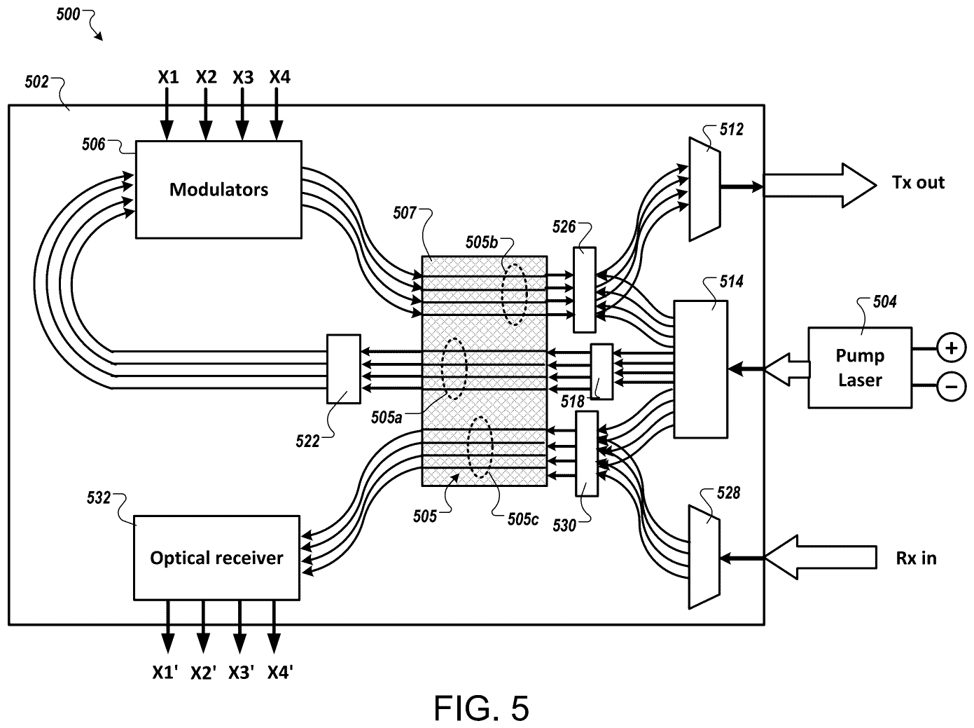

FIG. 5 illustrates an example of a fiber optic WDM transceiver showing both a transmitter and a receiver that utilize SOAs which are optically pumped by a single electrically pumped laser, according to implementations of the present disclosure. In this example, the optical transceiver 500 includes a PIC 502 that implements both transmitter and receiver components.

In this example, the external pump laser 504 generates input light which enters the silicon photonics PIC 502 and is split twelve ways by a splitter 514 and the split light beams are guided through SiN waveguides into a semiconductor die 507 (e.g., a III-V semiconductor die) in which twelve SOAs are implemented in the SOA array 505. The middle four SiN waveguides that are output from the splitter 514 pass through gratings 518 and proceed to the middle four SOAs 505a in the SOA array 505, which serve as optical gain for lasers, the outputs of which are guided through Si waveguides through a loop reflector 522 and proceed to the four modulators 506. The modulators 506 modulate the light with respective data X1, X2, X3, and X4 and output the modulated light signals into the upper four SOAs 505b of the SOA array 505, where they are amplified. The upper four SOAs 505b are backward pumped by the optical pump 504 via pump couplers 526, and the outputs are multiplexed by a CWDM multiplexer 512 for transmission (e.g., over an optical fiber link).

In addition, the PIC 502 also implements receiver operations. For example, light signals are received (e.g., from an optical fiber link) and demultiplexed by CWDM multiplexer 528. The four demultiplexed light signals proceed to the lower four SOAs 505c in the SOA array 505, where they are amplified. The lower four SOAs 505c are pumped by the optical pump 504 via pump couplers 530. The outputs of the lower four SOAs 505c then proceed to the optical receiver 532 for detection and demodulation to generate estimated data X1′, X2′, X3′, and X4′.

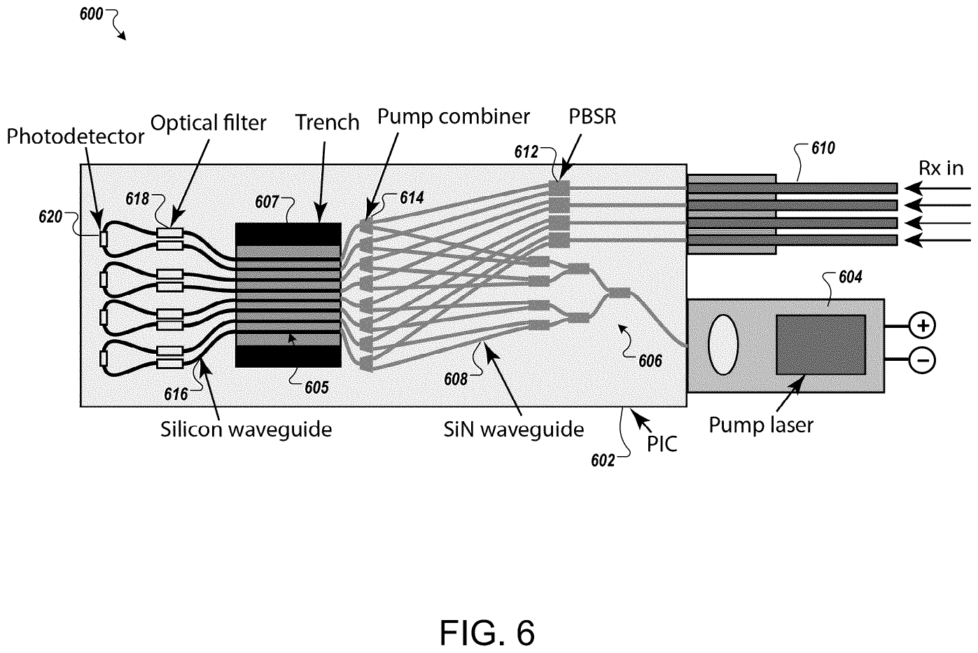

FIG. 6 illustrates an example of a fiber optic receiver based on polarization diversity that utilizes SOAs which are optically pumped by a single electrically pumped laser, according to implementations of the present disclosure. In this example, the optical transceiver 600 includes a PIC 602 that implements dual polarization (DP) receiver components.

In this example, the external pump laser 604 generates input light which enters the silicon photonics PIC 602 and is split eight ways by a splitter 606 and the split light beams are guided through SiN waveguides 608 into a semiconductor die 607 (e.g., a III-V semiconductor die) in which eight SOAs are implemented in the SOA array 605.

The optically pumped SOA array 605 provides amplification for light signals that are received (e.g., from an optical fiber link) through an input 610. In this example, four light signals are received, each of which utilizes dual polarization multiplexing, for a total of eight information signals. The received four light signals proceed through respective polarization beam splitter/rotators (PBSRs) 612 which separates each light signal into the two component polarizations. The resulting eight signals are input to pump combiners 614 to be combined with the optical pump light and enter the eight SOAs in the SOA array 605, where each light signal is amplified. The outputs of the eight SOAs 605 then proceed through respective Si waveguides 616 to optical filters 618 and photodetectors 620 for detection.

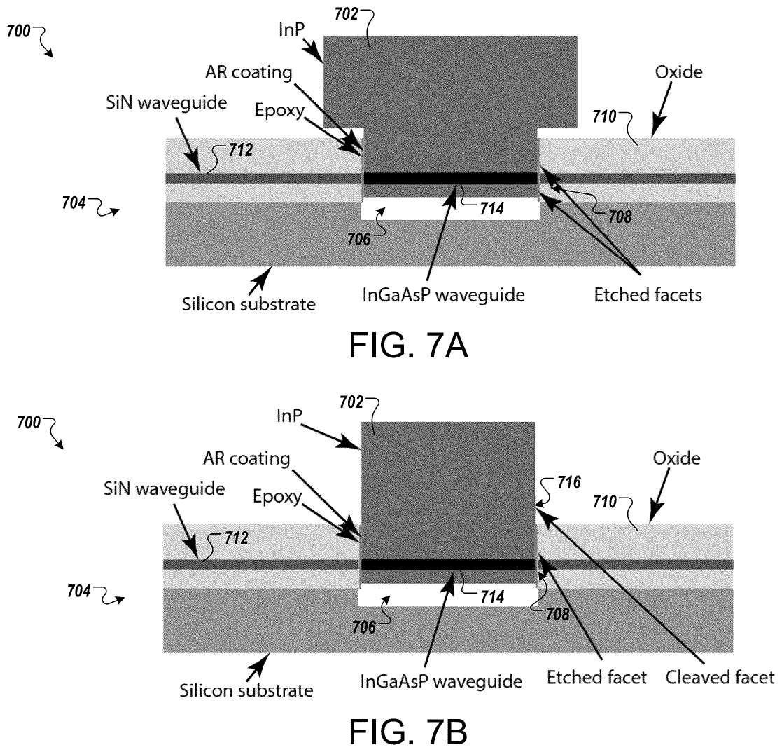

FIGS. 7A and 7B illustrate examples of a laser medium 700 implemented by integrating a III-V semiconductor (e.g., InP) chip into a silicon photonics chip, according to implementations of the present disclosure. The laser medium 700 of FIGS. 7A and 7B can be used for implementing an SOA array (e.g., SOA array 305, 405, or 505 in FIGS. 3, 4A, 4B, and 5) on a single III-V semiconductor chip (e.g., III-V chip 307, 407, or 507 in FIGS. 3, 4A, 4B, and 5).

In particular, the examples of FIGS. 7A and 7B show a side view of an integration of InP chip 702 into silicon photonics chip 704 which is implemented on a silicon substrate 705. In some implementations, the InP chip 702 (which implements the SOA array) is integrated into the silicon photonics chip 704 by placing the SOA array in a trench 706 in the silicon photonics chip 704. The trench 706 can be etched in the silicon photonics chip 704. In some implementations, the InP die 702 has etched facets 708 as shown in the example of FIG. 7A. However, in some implementations, instead of having etched facets 708, the InP die 702 can instead be cleaved to be slightly shorter than the length of the trench 706 in the silicon photonics chip 704, for example if a cleaving accuracy better than ˜+/−10 μm can be achieved. An example of the InP die 702 with cleaved facts 716 is shown in FIG. 7B.

In some implementations, the etched facets 708 of the InP die 702 are anti-reflection coated to match the refractive index of the oxide 710. The InP die 702 is actively aligned into the trench 706 of the silicon photonics chip 704. In some implementations, UV epoxy with a refractive index close to that of oxide can be placed at the etched facets 708 and cured using UV light. In some implementations, passive alignment can be utilized, for example by using cameras.

Light which is provided by the external optical pump source travels through a waveguide 712 (e.g., a SiN waveguide) in the silicon photonics chip 704 and is amplified as the light travels through a waveguide 714 (e.g., a InGaAsP waveguide) in the SOA array of the InP die 702. As discussed above, the SOA array in the InP die 702 is optically pumped, and therefore in some implementations the assembly of FIGS. 7A and 7B does not require soldering, electrical connections, or heat sinking.

Optically pumped SOAs can provide significant thermal advantages as compared to electrically pumped SOAs. As an example, consider an array of eight SOAs on a InP die 702 of dimension 1×1 mm² held down to a heat sink with a thermally conductive epoxy. Such epoxy typically has a thermal conductivity of 1 W/(mK), resulting in a thermal resistance for the SOA array equal to 30 C/W. Typical numbers for electrical pumping may be 50 mA in each SOA at 1.5 V. This results in 600 mW of power dissipation. Only a small fraction of this is carried away in optical power, and so it can be assumed that all of this power dissipation goes to thermal effects. This power dissipation will raise the temperature of the SOA die by 18° C. On the other hand, typical numbers of power dissipation for optical pumping may be 20 mW per SOA. Assuming half of this is goes to thermal effects, for an array of eight SOAs this results in 80 mW of power dissipation. This will raise the SOA die temperature by only 2.4° C. In this example, we can see that optical pumping raises the temperature 7.5 times less than electrical pumping. This enables the SOA to have significantly better performance at high environmental temperatures.

Optically pumped SOAs can provide one or more of the following technical advantages as compared to electrically pumped SOAs:
(i) Higher yield because the main failure mode in SOAs is related to current injection. The high yield, in turn, can enable the integration of large arrays.
(ii) Simpler packaging and assembly because no electrical connections or heat sinking are required. In some implementations, the SOA array can be simply epoxied to the PIC.
(iii) Simpler fabrication because no diode or metal are required. For example, in some implementations, the III-V wafer can be fabricated with only 1 or 2 processing steps.
(iv) Many SOAs can be placed very close together on a single die 702, because there are no electrical connections, and thermal dissipation is small. This can enable significant savings in cost, especially in scenarios where III-V material is expensive. This can also simplify packaging, because the tolerance to angular misalignment is larger when the waveguide spacing is smaller.
(v) Significantly improved performance because there is no heating from current injection (e.g., contact resistance and current leakage), and there is no optical loss from p-doping.
(vi) Easier to make with a low confinement factor, which reduces nonlinear effects, because there is no requirement for current injection.
(vii) Lower noise figure because there is no optical loss from p doping.
(viii) Easier to make with a large mode size for easier coupling to silicon photonics. For example, thick InGaAsP layers can be used, and they can be more easily buried, because there is no concern about junction placement and current confinement.
(ix) Enables use of a ridge waveguide with no regrowth.
(x) Smaller overall power consumption, because the optical pump source has a shorter wavelength and can be implemented in GaAs, which has a higher wall-plug efficiency and lower temperature dependence.
(xi) Enables implementation without the need for optical isolators, because the longer cavity of the integrated lasers reduces the maximum frequency of the relative intensity noise (RIN).

In general, optically pumped SOAs are not limited to the above technical advantages, and instead may enable other technical advantages. Furthermore, although the drawback of using optically pumped SOAs is the requirement for an optical pump source, this drawback can be mitigated by utilizing an array of multiple SOAs, all of which are simultaneously optically pumped by a single optical pump source.

Furthermore, although the examples discussed above were shown with four channels in the CWDM system, in general the system can implement greater than or fewer than four channels. Although the examples of FIGS. 3-5 illustrated optically pumped SOA arrays implemented with modulators in an optical transceiver, implementations are not limited to using SOA arrays with modulators. The optically pumped SOA arrays described above can be implemented in various scenarios, examples of which include intensity modulated direct detection (IM-DD) transceivers, coherent transceivers, and optical sensors. Some examples of possible configurations of optically pumped SOA arrays for these applications include:
(a) IMDD transmitter: The SOA array can be used to create the laser and an array of booster amplifiers.
(b) IMDD receiver: The SOA array can be used to create an array of pre-amplifiers.
(c) Coherent transmitter and receiver: The SOA array can be used to create a narrow-linewidth, frequency stabilized laser and a booster amplifier. The booster amplifier can be used before polarization combining.
(d) LiDAR FMCW sensor: The SOA array can be used to create the laser and an array of booster amplifiers.

Furthermore, in some implementations, the SOAs in the array can have different waveguide widths, depending on the function. For example, the SOAs in the array can have a narrower width when serving as laser gain media and a wider width when serving as booster amplifiers. If the employed wavelengths have a very wide spacing (e.g., greater than ˜80 nm), then two or more SOA array chips (e.g., such as SOA array chip 305, 405, 505) can be implemented, each with a different bandgap. In some implementations, heaters (which can be electrically controlled) may be integrated in the silicon photonics to temperature regulate the SOAs, which can reduce bandgap shift with ambient temperature changes. In some scenarios, the SOA arrays are especially suitable for co-packaged optics applications. In such scenarios, the optical pump source would be remote, and a single external optical pump source can provide optical pumping for multiple transceivers. In some implementations, the SOAs in the array may also have different material composition to have different bandgaps, which may be necessary to provide gain at different wavelengths on the same die. This could be done using regrowth or selective-area growth.

While this disclosure contains many specific implementation details, these should not be construed as limitations on the scope of any invention or of what may be claimed, but rather as descriptions of features that may be specific to particular implementations of particular inventions. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results.

What is claimed is:

1. An optical device comprising:
an input port configured to receive pumping light;
an optical splitter configured to split the pumping light into a plurality of waveguides; and
a plurality of semiconductor optical amplifiers (SOAs) implemented on a single III-V die, wherein each SOA is configured to be optically pumped by receiving a portion of the pumping light from a respective one of the plurality of waveguides.

2. The optical device of claim 1, further comprising at least one of an optical transmitter or an optical receiver.

3. The optical device of claim 1, further comprising an electrically pumped laser configured to provide the pumping light into the input port for optically pumping the plurality of SOAs.

4. The optical device of claim 3, wherein the input port, the optical splitter, the plurality of waveguides, the plurality of SOAs, and the single III-V die are implemented on a photonic die, and
wherein the electrically pumped laser is optically coupled to the photonic die.

5. The optical device of claim 1, wherein each SOA comprises:
an optical cavity configured to receive light from a waveguide among the plurality of waveguides; and
an optical gain medium in the optical cavity configured to amplify light that propagates through the SOA.

6. The optical device of claim 1, wherein one or more of the plurality of SOAs on the single III-V die have a center-to-center spacing less than or equal to 100 μm.

7. The optical device of claim 1, wherein one or more of the plurality of SOAs on the single III-V die have a center-to-center spacing less than or equal to 50 μm.

8. The optical device of claim 1, wherein each of the plurality of SOAs comprises etched facets.

9. The optical device of claim 8, wherein at least one of the etched facets are anti-reflection coated.

10. The optical device of claim 8, wherein the plurality of SOAs with etched facets are arranged in a trench in a photonic die with etched facets.

11. The optical device of claim 1, wherein the plurality of SOAs are attached to a silicon-photonics die with epoxy, solder, or other adhesive mechanism.

12. The optical device of claim 11, wherein the SOAs are epoxied upside down in a trench in the silicon-photonics die.

13. The optical device of claim 1, wherein for each SOA, there is no intentional p-type doping of semiconductor material near an active region of the SOA.

14. The optical device of claim 1, wherein there is no p-n junction in the SOAs.

15. The optical device of claim 1, wherein at least one of the plurality of SOAs is configured to provide optical gain in a laser cavity.

16. The optical device of claim 15, wherein at least one of the plurality of SOAs is configured to boost optical power of light that is output from an optical modulator.

17. The optical device of claim 16, wherein at least one of the plurality of SOAs is configured to pre-amplify optical power of light that is input to an optical receiver.

18. The optical device of claim 1, wherein a first SOA among the plurality of SOAs is configured to provide optical gain in a laser cavity, and
wherein a second SOA among the plurality of SOAs is configured as a booster amplifier for light that is output from an optical modulator.

19. The optical device of claim 1, wherein a first SOA among the plurality of SOA is configured as a booster amplifier for light that is output from an optical modulator, and
wherein a second SOA among the plurality of SOAs is configured as a pre-amplifier for light that is input to an optical receiver.

20. The optical device of claim 1, further comprising an electrically controllable heater in close proximity to the plurality of SOAs.

21. The optical device of claim 1, wherein each SOA comprises a waveguide configured to propagate light through the SOA, and
wherein the waveguide of each SOA is coupled to a respective silicon nitride (SIN) waveguide in the optical device.

22. The optical device of claim 1, wherein the optical splitter is configured to split the pumping light into the plurality of waveguides with adjustable splitting ratios.

23. The optical device of claim 1, further comprising a wavelength-division multiplexer connecting one of the plurality of waveguides to one of the SOAs that combines the pumping light and an input signal or an output signal.

24. An optical device comprising:
a photonics die comprising an array of semiconductor optical amplifiers (SOAs) implemented on a single semiconductor die with no used electrical contacts to the SOAs.

25. The optical device of claim 24, further comprising an electrical heater on the array of SOAs.

26. The optical device of claim 24, further comprising an electrically pumped laser configured to provide pumping light for optically pumping the array of SOAs.
